(19) United States
(12) Patent Application Publication
(10) Pub. No.: US 2008/0122413 A1
(43) Pub. Date: May 29, 2008

(54) METHOD AND APPARATUS FOR VERSATILE HIGH VOLTAGE LEVEL DETECTION WITH RELATIVE NOISE IMMUNITY

(76) Inventors: Boon-Aik Ang, Santa Clara, CA (US); Nian Yang, Mountain View, CA (US); Yonggang Wu, Santa Clara, CA (US)

Correspondence Address: INGRASSIA FISHER & LORENZ, P.C., 7150 E. CAMELBACK, STE. 325, SCOTTSDALE, AZ, 85251, US

(21) Appl. No.: 11/423,643

(22) Filed: Jun. 12, 2006

(51) Int. Cl. G05F 1/10; G01R 19/00

(52) U.S. Cl. 323/234; 324/76.11

(57) ABSTRACT

A method and apparatus are provided for versatile high voltage level detection. A semiconductor device (100) is provided which includes a high voltage generating circuit (202) for generating a high voltage supply signal having a high voltage level and a voltage level detector (204) coupled to the output of the high voltage generating circuit (202) and including a current source (402) for generating a current to increase the voltage margin of the voltage level detector (204), the voltage level detector (204) generating a voltage control signal in response to the current and the high voltage level detected.

### FIELD OF THE INVENTION

The present invention generally relates to semiconductor high voltage generating circuits, and more particularly relates to a method and apparatus for reduced noise high voltage level detection.

### BACKGROUND OF THE INVENTION

Drain pumps and similar high voltage generating circuits are utilized to provide high voltage and/or high current for semiconductor operation. For example, in semiconductor memory devices, drain pumps are used to provide high voltage and high current for programming memory cells. For improved operation of drain pumps, power conservation thereby, efficient operation and other operational control of drain pumps, accurate high voltage detection must be perfomed. Voltage detection circuits, however, require a connection to the high voltage output of the drain pumps with little or no noise thereon. Typically, drain pumps include large capacitors. To conserve power, the drain pumps are turned on and off frequently depending on the output voltage thereof. Because of the capacitors, each time the drain pumps are turned on or turned off, they create noise on the high voltage output thereof. In addition, while the drain pumps are ramping up to a steady state voltage level after being turned on, they also create noise on the power buses. This noise increases as the size of the drain pump increases and is unacceptable for reliable and versatile high voltage detection.

Accordingly, it is desirable to provide a method and apparatus for versatile high voltage detection with immunity to a noisy environment. Furthermore, other desirable features and characteristics of the present invention will become apparent from the subsequent detailed description of the invention and the appended claims, taken in conjunction with the accompanying drawings and this background of the invention.

### BRIEF SUMMARY OF THE INVENTION

A method and apparatus is provided for increased noise immunity for a voltage detection circuit by dividing down a high voltage level in response to a current from a current source to generate a level shifted signal and detecting the high voltage level of a high voltage supply signal in response to the level shifted signal.

### BRIEF DESCRIPTION OF THE DRAWINGS

The present invention will hereinafter be described in conjunction with the following drawing figures, wherein like numerals denote like elements, and

FIG. 1 is a block diagram of a semiconductor memory device in accordance with the present invention;

FIG. 2 is a block diagram of a high voltage generator in accordance with an embodiment of the present invention;

FIG. 3 is a diagram of a conventional high voltage detector for use in the high voltage generator of FIG. 2; and

FIG. 4 is a diagram of a high voltage detector for use in the high voltage generator of FIG. 2 in accordance with the embodiment of the present invention.

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

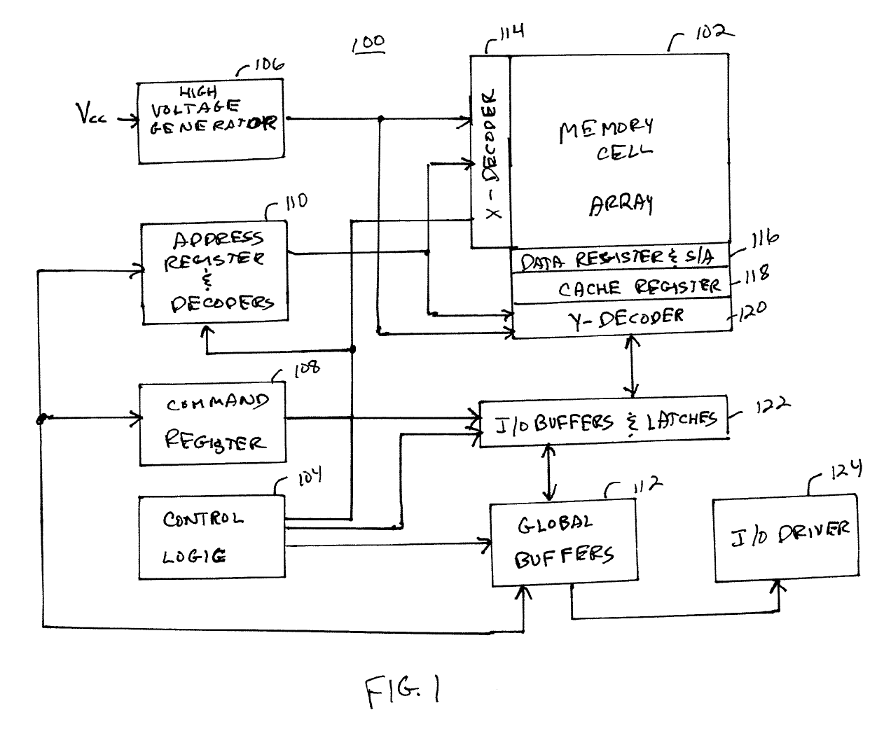

Referring to FIG. 1, a semiconductor device 100, such as a non-volatile semiconductor memory device, includes a memory cell array 102, control logic 104 such as a state machine, a high-voltage generator 106, a command register 108, an address register and decoder 110, a global buffer 112, an X-decoder 114, a data register and sense amplifier 116, a cache register 118, a Y-decoder 120, an Input/Output (I/O) buffer and latch circuit 122, and an input/output driver 124.

The memory cell array 102 includes rewritable non-volatile memory cells that are arranged along word lines and bit lines in a matrix fashion well-known to those skilled in the art. Each of the memory cells is a cell wherein the write function is performed through hot electron injection. In this embodiment, SONOS-type cells may be employed as the non-volatile memory cells. The state machine 104 controls the operation of each circuit in the device in response to each control signal.

In accordance with the present invention, the high-voltage generator 106 generates high voltages that are used within the semiconductor device for memory operations thereof by applying the high voltages to selected cells within the memory cell array 102 via the X-Decoder 114 and the Y-Decoder 120. The high voltages used within the semiconductor memory device include a high voltage for writing data, a high voltage for erasing data, a high voltage for reading data, and a verifying high voltage for checking whether sufficient write/erase has been performed on a subject memory cell at the time of writing or erasing data.

The command register 108 temporarily stores operation commands that are input through the global buffer 112. The address register and decoder 110 temporarily stores input address signals. The I/O buffer and latch circuit 122 controls various signals or data corresponding to I/O terminals. The input/output driver 124 controls the data to be output from the semiconductor memory device 100 and the data to be input thereto.

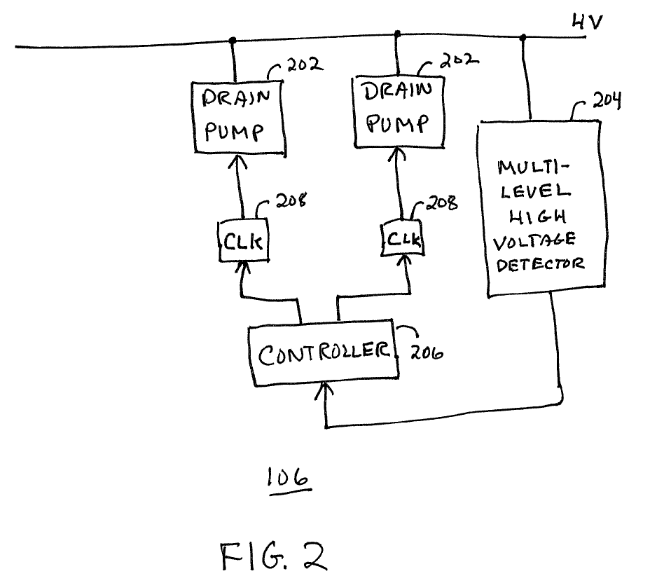

Referring to FIG. 2, a high-voltage generator 106 in accordance with an embodiment of the present invention includes one or more high voltage generating circuits such as drain pumps 202 for generating the voltage signals having a high voltage level. Multiple drain pumps 202 could be used to maintain a high voltage level while providing power savings by turning on and off one or another of the drain pumps 202. A multi-level voltage detector 204 is coupled to the output of the drain pump 202 and generates a voltage control signal in response to the high voltage level detected at the output of the drain pump 202. The voltage control signal is supplied to a controller 206 for switching the drain pumps 202 on and off or, in accordance with this embodiment of the present invention where the drain pumps 202 have an operating frequency under control of clocks 208, switching the clocks 208 on and off to switch the drain pumps 202 on and off.

In addition to simple clocks, the clocks 208 may include a clock and one or more clock signal dividers. A plurality of clock signals are generated by a base clock signal from the clock and the base clock signal passing through the one or more clock signal dividers, such as frequency dividers, coupled in series with the clock. One of the plurality of clock signals is chosen by the voltage control signal, acting as a clock selection signal, being provided to a clock signal selector, such as a multiplexer, which receives the plurality of clock signals, the one of the plurality of clock signals selected in response to the clock selection signal. In the embodiment depicted in FIG. 2, the voltage level detector 204 is a two-level detector and the two-level voltage control signals switch the two clocks 208 on and off. Alternatively multiple clock signal dividers could be used and a plurality of operating clock signals could be tapped from the output of the clock 208 and the clock signal dividers. Therefore, depending on the high voltage level detected by the multi-level detector 204, a multi-level voltage control signal could select different ones of the plurality of clock signals to control the operation frequency of one of the drain pump 202. In this manner, lower frequency clock signals could be selected to achieve high voltage generator 106 current savings, thereby providing a method for power conservation in the semiconductor device 100. Efficient operation of the high voltage generator 106 provides both additional power conservation and reliable operation. Whichever implementation is used, accurate voltage detection by the multi-level high voltage detector 204 is necessary, even in high noise environments, to achieve efficient operation of and current savings by the high voltage generator 106.

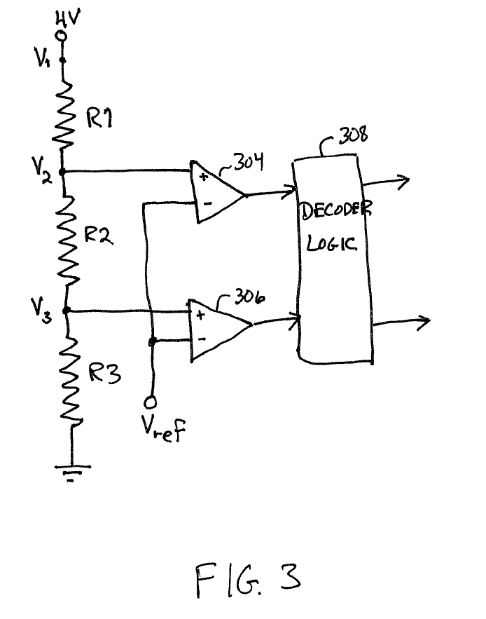

FIG. 3 depicts a conventional two level high voltage detector 204. A voltage dividing circuit 302, such as a resistor bridge circuit, includes resistors R1, R2 and R3 coupled in series between ground and a high voltage supply signal from the drain pump 202 having a high voltage level. The resistor bridge circuit generates voltages V₂ and V₃ which, when compared to a reference voltage Vref by comparators 304, 306, provide voltage control signals to a detection controller 308 to provide the multiple voltage control signals to control the drain pumps 202. The resistors R2 and R3 are used to divide the voltage down to the Vref level for appropriate comparison with Vref in accordance with the following equations:

V₂=HV* ((R2+R3)/(R1+R2+R3)) (1)

V₃=HV* (R3/(R1+R2+R3)) (2)

For a high voltage supply signal having a high voltage level approximately equal to eight volts, such as a high voltage level used for high voltage semiconductor memory operations, and a Vref approximately equal to one volt, to detect voltage differences in the high voltage level within a 500 millivolt (mV) range (e.g., between 7.5 volts and 8.0 volts), the voltage margin detectable in V₂ and V₃ must necessarily be 62.5 mV as calculated by the equation

Voltage Margin=Target Voltage Difference/(V₁/Vref) (3)

where the V₁ is the high voltage level HV.

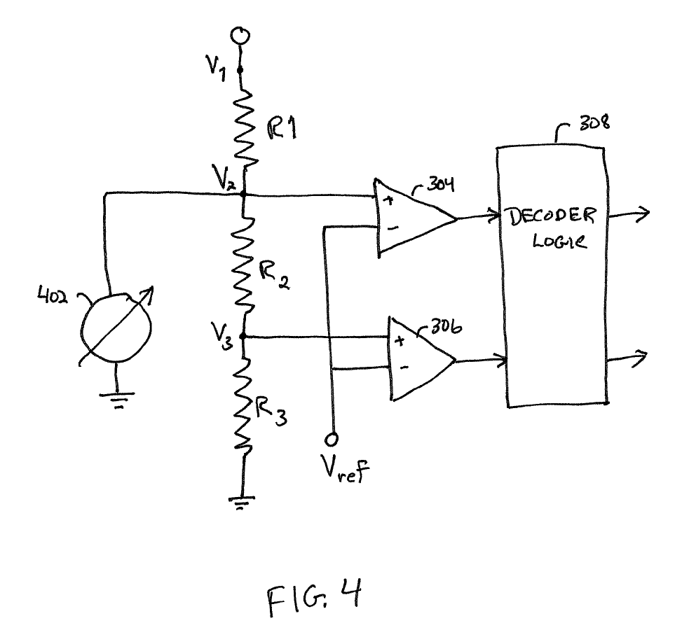

A voltage margin or band gap voltage range must be large enough to reliably detect a change in voltage even in a noisy environment, providing reliable voltage detection decisions. Referring to FIG. 4, a multi-level high voltage detector 204 in accordance with the present invention provides an increased voltage margin with the addition of a current source 402 supplying a current I_{CS} to the junction of R1′ and R2′. With the addition of the current source 402, the high voltage level is divided or shifted down in response to the current I_{CS} to generate level shifted signals having voltages V₁′, V₂′ and V₃′, the voltage control signal being generated in response to the level shifted signal. The current I_{CS} can be expressed as

I_{CS}=Vref/Rref (4)

### Since addition of the current source 402 divides down the high voltage level by I_{CS}*R1, the equations to calculate V₂′ and V₃′ are as follows

V₂′=(HV−I_{CS}*R1′)*((R2′+R3′)/(R1′+R2′+R3′)) (5)

V₃′=(HV−I_{CS}* R1′)*(R3′/(R1′+R2′+R3′)) (6)

When the current source 402 is chosen to provide a current such that I_{CS}*R1′ equals four volts (where the high voltage level is eight volts and Vref is one volt), then V₁′ is equal to approximately four volts. For a 500 mV detection range at high voltage, using equation (3), the voltage margin is approximately 125 mV. Thus, the present invention increases the voltage margin by one hundred percent providing a versatile high level voltage detector 204 with increased immunity to a noisy environment.

While the current source 402 is depicted as a current reference circuit, the current source could also be a current-steering digital-to-analog converter that changes its current value depending on its mode of operation. For example, at different high voltage levels the current source 402 would provide a different voltage shift.

While at least one exemplary embodiment has been presented in the foregoing detailed description of the invention, it should be appreciated that a vast number of variations exist. For example, instead of a semiconductor memory device, the present invention could be implemented in any semiconductor device utilizing a high voltage detector. In addition, instead of a two level detector, a three or more level detector could be implemented using the present invention. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims and their equivalents.

What is claimed is:

1. A method for detection of a high voltage level of a high voltage supply signal comprising the steps of:
dividing down the high voltage level in response to a current from a current source to generate a level shifted signal; and
detecting the high voltage level of the high voltage supply signal in response to the level shifted signal.

2. The method of claim 1 wherein the step of dividing down the high voltage level comprises the step of dividing down the high voltage level in response to the current and a reference voltage to detect the level shifted signal within a band gap voltage range, the band gap voltage range determined in response to the current and the reference voltage.

3. The method of claim 1 wherein the high voltage supply signal is generated by a plurality of high voltage generating circuits, the method further comprising the step of controlling the plurality of high voltage generating circuits in response to the high voltage level detected.

4. The method of claim 1 wherein the high voltage supply signal is generated by a high voltage generating circuit, the method further comprising the step of controlling the high voltage generating circuit in response to the high voltage level detected.

5. The method of claim 4 wherein the step of detecting the high voltage level comprises the step of generating a voltage control signal in response to the high voltage level detected, and wherein the step of controlling the high voltage generating circuit comprises the step of controlling the high voltage generating circuit in response to the voltage control signal.

6. The method of claim 5 wherein the step of controlling the high voltage generating circuit in response to the voltage control signal comprises the step of controlling an operation frequency of the high voltage generating circuit in response to the voltage control signal.

7. The method of claim 6 wherein the step of controlling an operation frequency of the high voltage generating circuit comprises the steps of:
selecting an operating clock signal of one of a plurality of clock signal generators in response to the voltage control signal; and
providing the selected operating clock signal to the high voltage generating circuit for controlling the operation frequency thereof.

8. A semiconductor device comprising:
a high voltage generating circuit generating a high voltage supply signal having a high voltage level;
a voltage dividing circuit coupled to the high voltage generating circuit and including a current source, the voltage dividing circuit dividing down the high voltage level in response to a current from the current source to generate a level shifted signal; and
a controller coupled to the voltage dividing circuit and the high voltage generating circuit to control the high voltage level of the high voltage supply signal in response to the level shifted signal.

9. The semiconductor device of claim 8 wherein the voltage dividing circuit is coupled to a reference voltage, the voltage dividing circuit dividing down the high voltage level in response to the current and the reference voltage to detect the level shifted signal within a band gap voltage range, the band gap voltage range determined in response to the current and the reference voltage.

10. A semiconductor device comprising:
a high voltage generating circuit for generating a high voltage supply signal having a high voltage level; and
a voltage level detector coupled to the output of the high voltage generating circuit and including a current source for generating a current to increase the voltage margin of the voltage level detector, the voltage level detector generating a voltage control signal in response to the current and the high voltage level detected thereat.

11. The semiconductor device of claim 10 wherein the voltage level detector generates a two-level voltage control signal, and wherein the high voltage generating circuit turns on or off in response to a level of the two-level voltage control signal.

12. The semiconductor device of claim 10 wherein the high voltage generating circuit comprises a plurality of high voltage level producing drain pumps, and wherein the voltage control signal comprises a plurality of drain pump control signals, each of the plurality of high voltage level producing drain pumps turned on or off in response to one of the plurality of drain pump control signals.

13. The semiconductor device of claim 10 wherein the voltage level detector also includes a resistor bridge circuit comprising at least one resistor, the voltage level detector generating a voltage control signal in response to the current, the high voltage level detected and a resistive value of one or more of the at least one resistor.

14. The semiconductor device of claim 10 wherein the voltage level detector receives a reference voltage and generates the voltage control signal in response to the current, the high voltage level detected and the reference voltage.

15. The semiconductor device of claim 10 wherein the voltage level detector divides down the high voltage level in response to the current from the current source to generate a level shifted signal, the voltage control signal generated in response to the level shifted signal.

16. The semiconductor device of claim 15 wherein the voltage level detector receives a reference voltage and generates the voltage control signal in response to the level shifted signal and the reference voltage.

17. The semiconductor device of claim 10 further comprising a controller coupled to the voltage level detector and the high voltage generating circuit to control the high voltage generating circuit in response to the voltage control signal.

18. The semiconductor device of claim 17 wherein the controller controls an operation frequency of the high voltage generating circuit in response to the voltage control signal.

19. The semiconductor device of claim 18 wherein the controller includes a plurality of clock signal generators, each of the plurality of clock signal generators generating an operating clock signal, the controller selecting an operating clock signal of one of the plurality of clock signal generators in response to the voltage control signal and providing the selected operating clock signal to the high voltage generating circuit to control the operation frequency thereof.

20. The semiconductor device of claim 19 wherein the voltage level detector comprises a multi-level voltage detector for generating a clock selection signal as the voltage control signal, and wherein the controller includes a clock signal selector for selecting one of a plurality of clock signals to control the operation frequency of the high voltage generating circuit.
